(19) United States
(12) Patent Application Publication
(10) Pub. No.: US 2015/0085197 A1
(43) Pub. Date: Mar. 26, 2015

(54) VIDEO DISPLAY DEVICE

(71) Applicant: ALPS ELECTRIC CO., LTD., Tokyo (JP)

(72) Inventor: Toru Yoshida, Miyagi-ken (JP)

(73) Assignee: ALPS ELECTRIC CO., LTD.

(21) Appl. No.: 14/457,542

(22) Filed: Aug. 12, 2014

(30) Foreign Application Priority Data
Sep. 26, 2013 (JP) 2013-199773

(51) Int. Cl. H04N 9/31; H01S 5/0683; H04N 5/74; H01S 5/024

(52) U.S. Cl. CPC H04N 9/3144; H01S 5/02469; H01S 5/06837; H01S 5/06832; H04N 5/7475
USPC 348/748

(57) ABSTRACT

A video display device includes a laser beam source module including a laser beam source emitting a laser beam and a laser beam source drive unit supplying power to the laser beam source, and an image generation unit generating a desired display image from the laser beam. The laser beam source module includes a substrate having the placed laser beam source and improved thermal conductivity, a temperature measurement member measuring a temperature of the substrate, a temperature adjustment member contacting the substrate and adjusting the temperature of the substrate, a circuit substrate electrically connecting the temperature measurement member and the laser beam source. Moreover, the circuit substrate is disposed on a rear surface opposite to a placement surface on which the laser beam source is placed, the temperature measurement member is mounted on the circuit substrate, and a portion of the temperature measurement member is connected to the substrate.

### CLAIM OF PRIORITY

This application claims benefit of priority to Japanese Patent Application No. 2013-199773 filed on Sep. 26, 2013, which is hereby incorporated by reference in its entirety.

### BACKGROUND

1. Field of the Disclosure

The present disclosure relates to a video display device using a laser beam, and particularly, relates to a video display device which has improved radiation stability of the laser beam and is visually confirmed with a stable display image.

2. Description of the Related Art

In recent years, a laser beam is applied to a wide range of fields such as an optical recording device, a measuring instrument, a printer, a medical instrument, a business machine, or the like which uses characteristics such as a small size, high efficiency, or high directivity. Particularly, recently, a video display device, which radiates the laser beam from the laser beam source to a projection surface such as a screen or a wall using the laser light source and displays an image, is generally known. When the laser beam source is applied to the video display device, it is necessary to stably display a display image which is visually confirmed by an observer, and thus, a stable radiation of the laser beam source is important. Particularly, in the laser beam source, self heat generation is increased according to the radiation of the laser beam, and in most cases, a change in the temperature of the laser beam source due to the heat generation generates instability of the radiation.

Japanese Unexamined Patent Application Publication No. 2011-117849 suggests a device including a configuration which suppresses the change of the temperature due to the heat generation, in, a light source module 910 shown in FIGS. 12A and 12B. In related art, FIGS. 12A and 12B are views illustrating an object detection device which detects an object inside a target region based on a state of a reflected light when light is projected to a target region, FIG. 12A is a view showing configurations of a light source module 910 and a light receiving module 920 which are configurations of an optical unit in an information acquisition device of an object detection device, and FIG. 12B is a cross-sectional configuration view showing the details of the light source module 910.

The light source module 910 and the light receiving module 920 shown in FIG. 12A are disposed on a long chassis 830 laterally in an X axis direction. The chassis 830 is a plate shape member, which is configured of a metal having high thermal conductivity, and has a function, which radiates heat of components (here, light source module 910 and light receiving module 920) disposed on the chassis 830. Moreover, the light source module 910 shown in FIG. 12B is configured to include a laser beam source 911 including a semiconductor laser, a laser holder 916 holding a laser beam source 911, a temperature conditioning element 912 disposed to be adjacent to the laser holder 916, a temperature sensor 913 disposed to contact a side surface of the laser holder 916, a projection lens 914 projecting the laser beam outside the cover 915 over the entire target region, and a wiring 917 connected to a terminal 911t of the laser beam source 911 and a circuit substrate 801. The temperature conditioning element 912 uses a thermoelectric element such as a Peltier element, adjusts the temperature of the laser beam source 911 by heating or cooling the laser beam source 911 from information of the temperature sensor 913, and causes a wavelength of the laser beam emitted from the laser beam source 911 to be maintained at an optimal wavelength.

However, in the related art, since the temperature sensor 913 is disposed to contact the side surface of the laser holder 916, the temperature sensor indirectly detects the temperature of the laser beam source 911 (CAN) via the laser holder 916. Accordingly, in the configuration, an error occurs between an actual temperature of the laser beam source 911 and the detected temperature of the temperature sensor 913. FIG. 13 is a graph showing a relationship between the detected temperature of the temperature sensor 913 and a wavelength of the laser beam according to the laser beam source 911 in the related art. As shown in FIG. 13, in the laser beam source 911 of the related art, an error occurs between the detected temperature of the temperature sensor 913 and the actual temperature of the laser beam source 911, and thus, due to the error, an error occurs in the wavelength of the laser beam emitted from the laser beam source 911. In general, when the laser beam is applied to the video display device, due to the error of the wavelength, instability occurs on a display image visually confirmed by an observer, and thus, in order to suppress the error of the wavelength of the laser beam, correct temperature management is needed.

Moreover, in the laser holder 916 of the related art, it is described that the thermal conductivity is performed by only the member having the thermal conductivity, and thus, if the thermal conductivity is not favorable, a time lag occurs between the actual temperature of the laser beam source 911 and the detected temperature of the temperature sensor 913. In general, when the laser beam is applied to the video display device, due to time lag, instability occurs on a display image visually confirmed by an observer, and thus, in order to suppress the time lag of the wavelength of the laser beam, a method having improved responsiveness needs.

On the other hand, if the temperature sensor 913 is disposed in the vicinity of the laser beam source 911, the temperature error or the time lag is decreased. However, in this case, there is a problem in that it is not easy to electrically connect the temperature sensor 913 and the circuit substrate 801 to each other. Actually, in the related art, the connection between the temperature sensor 913 disposed to contact the side surface of the laser holder 916 and the circuit substrate 801 is not disclosed, and thus, it is described that the connection method is not easily performed.

### SUMMARY

A video display device allowing an observer to observe video of a display image, includes: a laser beam source module including a laser beam source emitting a laser beam and a laser beam source drive unit supplying power to the laser beam source; and an image generation unit generating a desired display image from the laser beam. The laser beam source module includes: a substrate on which the laser beam source is mounted and which has improved thermal conductivity; a temperature measurement member measuring a temperature of the substrate; a temperature adjustment member contacting the substrate and adjusting the temperature of the substrate; and a circuit substrate electrically connecting the temperature measurement member and the laser beam source. The circuit substrate is disposed on a rear surface opposite to a placement surface on which the laser beam source is placed, the temperature measurement member is mounted on the circuit substrate, and a portion of the temperature measurement member is connected to the substrate.

### BRIEF DESCRIPTION OF THE DRAWINGS

FIG. 1 is a configuration view illustrating a video display device of a first embodiment of the present invention;

FIGS. 2A and 2B are configuration views illustrating a laser beam source module according to the video display device of the first embodiment of the present invention, FIG. 2A is a top perspective view of a unit on which the laser beam source is mounted, and FIG. 2B is a bottom perspective view of the unit on which the laser beam source is mounted;

FIGS. 3A and 3B are configuration views illustrating the laser beam source module according to the video display device of the first embodiment of the present invention, FIG. 3A is a top view of the unit on which the laser beam source is mounted, and FIG. 3B is a bottom view of the unit on which the laser beam source is mounted;

FIGS. 4A and 4B are configuration views illustrating the laser beam source module according to the video display device of the first embodiment of the present invention, FIG. 4A is a front view when the module is viewed from an Y2 side shown in FIG. 2A, and FIG. 4B is a cross-sectional view taken along line IV-IV shown in FIGS. 3A and 3B;

FIGS. 5A and 5B are configuration views illustrating the laser beam source module according to the video display device of the first embodiment of the present invention, FIG. 5A is a side view when the module is viewed from an X1 side shown in FIG. 2A, and FIG. 5B is a cross-sectional view taken along line V-V shown in FIGS. 3A and 3B;

FIG. 6 is a configuration view illustrating a video display device of a second embodiment of the present invention;

FIGS. 7A and 7B are configuration views illustrating a laser beam source module according to the video display device of the second embodiment of the present invention, FIG. 7A is a top perspective view of a unit on which the laser beam source is mounted, and FIG. 7B is a bottom perspective view of the unit on which the laser beam source is mounted;

FIGS. 8A and 8B are configuration views illustrating the laser beam source module according to the video display device of the second embodiment of the present invention, FIG. 8A is a top view of the unit on which the laser beam source is mounted, and FIG. 8B is a bottom view of the unit on which the laser beam source is mounted;

FIGS. 9A and 9B are configuration views illustrating the laser beam source module according to the video display device of the second embodiment of the present invention, FIG. 9A is a front view when the module is viewed from an Y2 side shown in FIG. 7A, and FIG. 9B is a cross-sectional view taken along line IX-IX shown in FIGS. 8A and 8B;

FIGS. 10A and 10B are configuration views illustrating the laser beam source module according to the video display device of the second embodiment of the present invention, FIG. 10A is a side view when the module is viewed from an X1 side shown in FIG. 7A, and FIG. 10B is a cross-sectional view taken along line X-X shown in FIGS. 8A and 8B;

FIGS. 11A and 11B are views illustrating an modification of the embodiment of the present invention, FIG. 11A is a bottom view of a first modification of the first embodiment, and FIG. 11B is a bottom view of a third modification of the first embodiment;

FIGS. 12A and 12B are views illustrating an object detection device which detects an object inside a target region based on a state of the reflected light when light is projected to the target region in the related art, FIG. 12A is a view showing configurations of a light source module and a light receiving module which are configurations of an optical unit in an information acquisition device of an object detection device, and FIG. 12B is a cross-sectional configuration view showing the details of the light source module; and

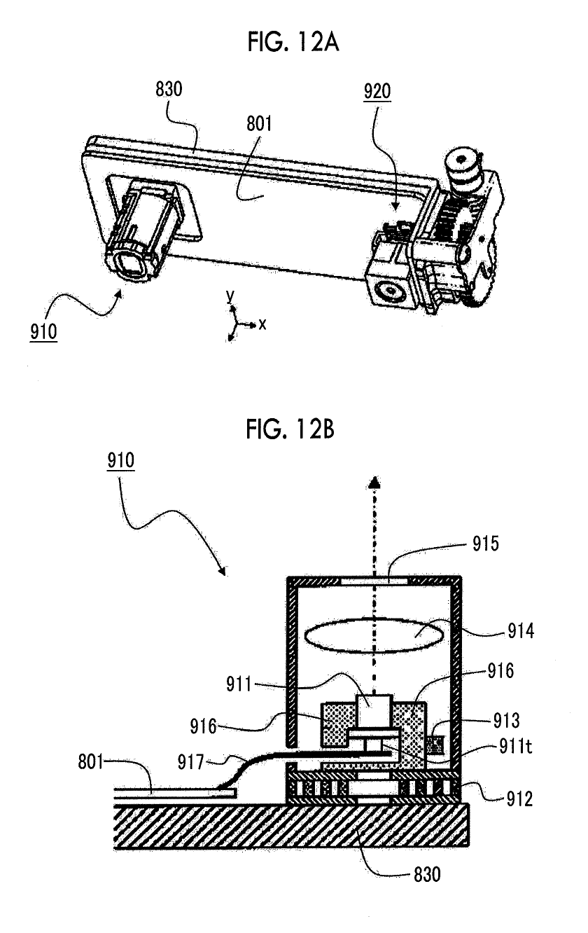

FIG. 13 is a graph showing a relationship between the detected temperature of the temperature sensor and a wavelength of the laser beam according to the laser beam source in the related art.

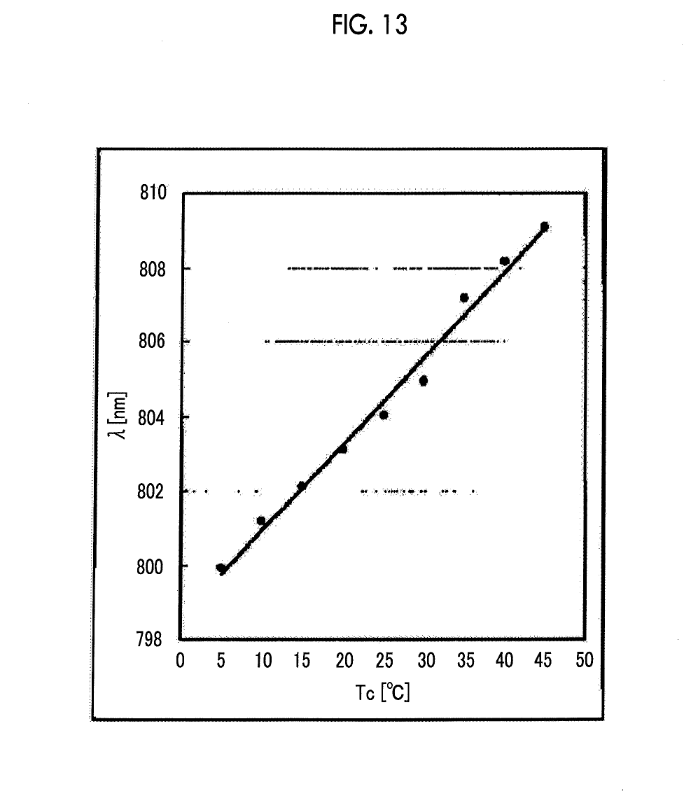

### DESCRIPTION OF THE EXEMPLARY EMBODIMENTS

Hereinafter, an embodiment of the present invention will be described with reference to the drawings.

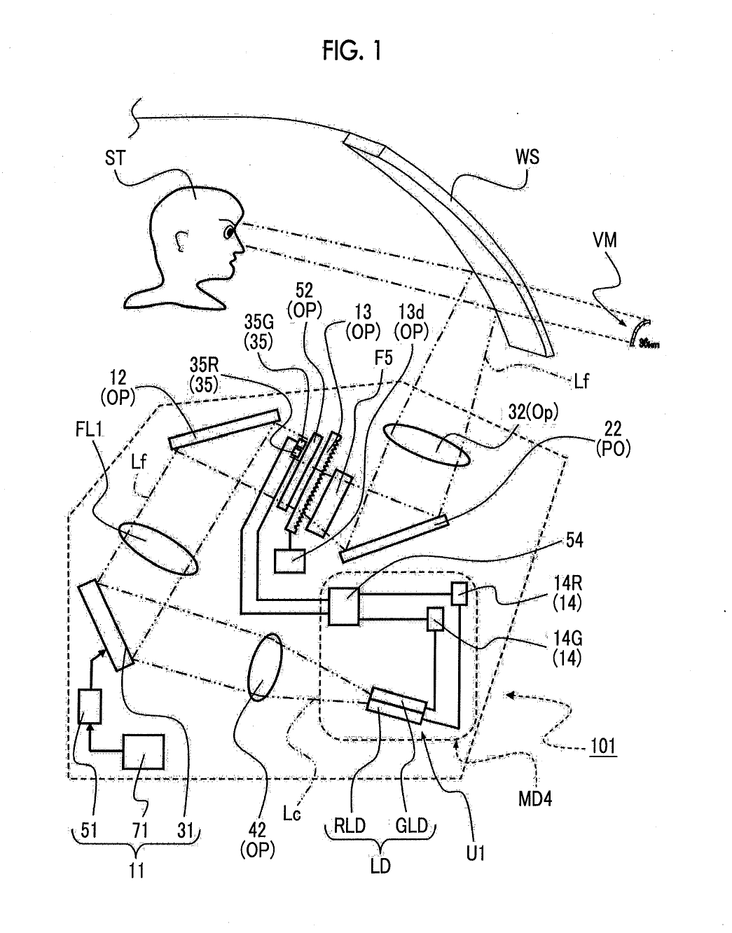

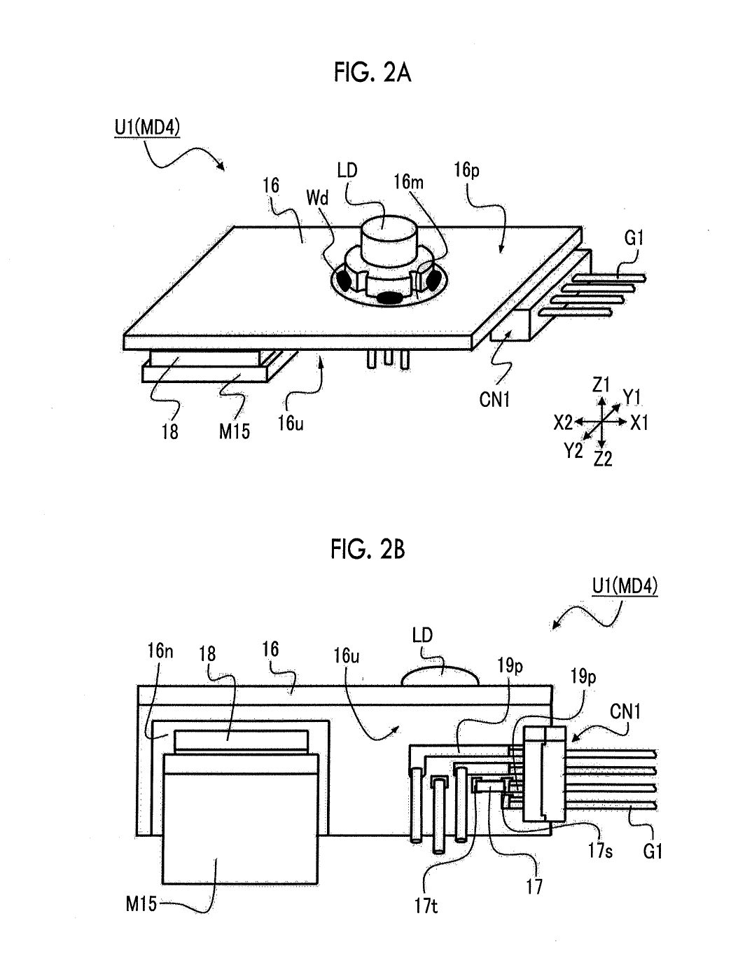

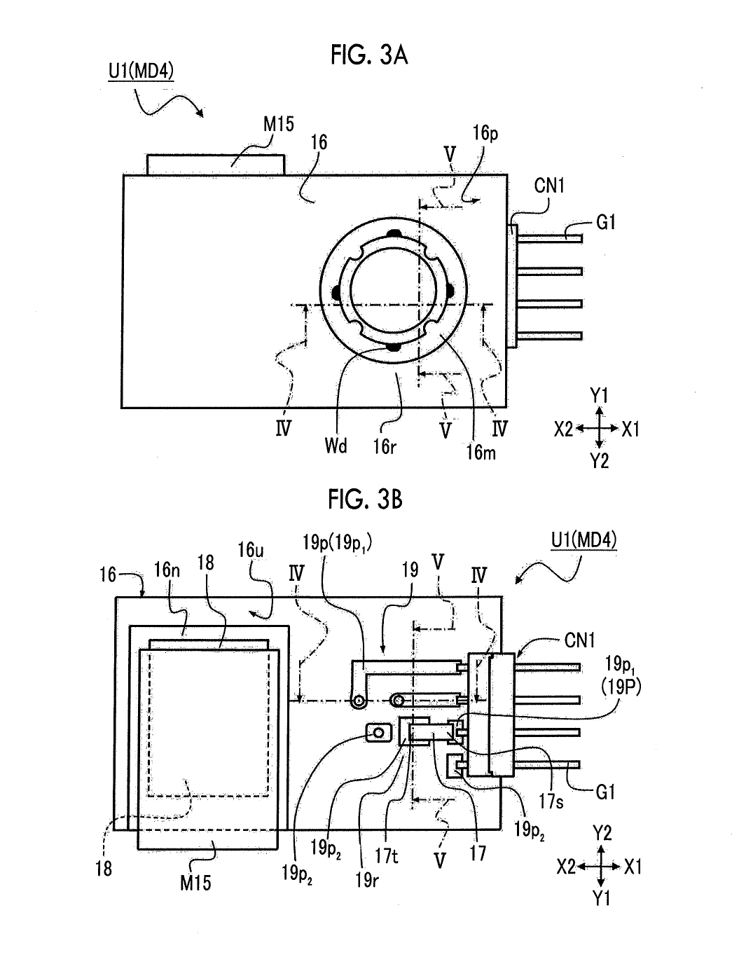

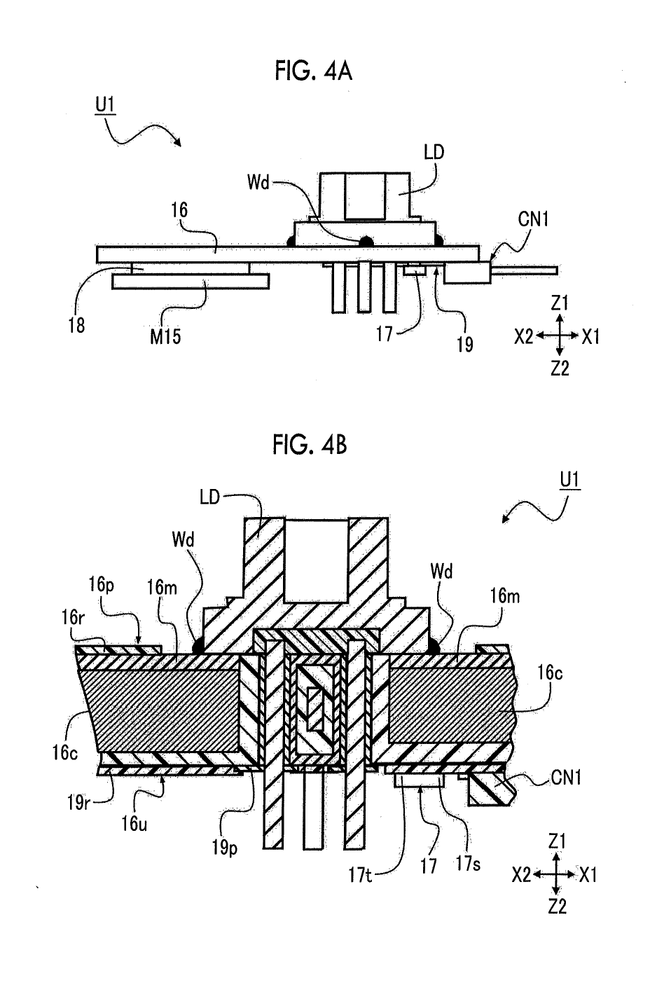

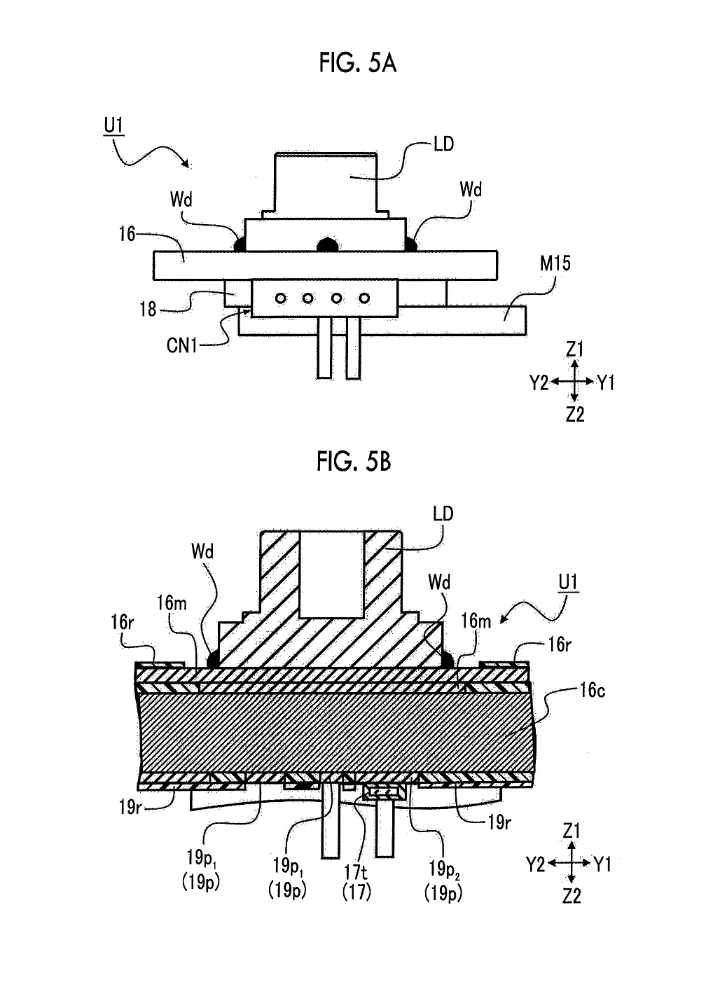

FIG. 1 is configuration view illustrating a video display device 101 of a first embodiment of the present invention. FIGS. 2A and 2B are configuration views illustrating a laser beam source module according to the video display device of the first embodiment of the present invention, FIG. 2A is a top perspective view of a unit U1 on which the laser beam source LD is mounted, and FIG. 2B is a bottom perspective view of the unit U1 on which the laser beam source LD is mounted. FIGS. 3A and 3B are configuration views illustrating the laser beam source module according to the video display device of the first embodiment of the present invention, FIG. 3A is a top view of the unit U1 on which the laser beam source LD is mounted, and FIG. 3B is a bottom view of the unit U1 on which the laser beam source LD is mounted. FIGS. 4A and 4B are configuration views illustrating the laser beam source module according to the video display device of the first embodiment of the present invention, FIG. 4A is a front view when the module is viewed from an Y2 side shown in FIG. 2A, and FIG. 4B is a cross-sectional view taken along line IV-IV shown in FIGS. 3A and 3B. FIGS. 5A and 5B are configuration views illustrating the laser beam source module according to the video display device of the first embodiment of the present invention, FIG. 5A is a side view when the module is viewed from an X1 side shown in FIG. 2A, and FIG. 5B is a cross-sectional view taken along line V-V shown in FIGS. 3A and 3B.

As shown in FIG. 1, the video display device 101 of the first embodiment of the present invention is mounted on a vehicle, particularly, on an automobile, and is used as a video display device for providing vehicle information with respect to a drive (observer) ST.

As shown in FIG. 1, the video display device 101 of the first embodiment of the present invention is configured to include a laser beam source module MD4 that includes the laser beam source LD emitting a laser beam Lc, and an image generation unit 11 that generates a desired display image from the laser beam Lc. Moreover, the video display device 101 includes an optical member OP which introduces video light Lf of the display image to a windshield WS of the vehicle, and a light intensity detection unit 35 which detects light intensity of the video light Lf. Moreover, a video VM of the display image generated by an image generation unit 11 is observed (visually confirmed) through the windshield WS by the observer (driver) ST.

First, a laser beam source module MD4 of the video display device 101 will be described. As shown in FIG. 1, the laser beam source module MD4 is configured to include a unit U1 that includes a laser beam source LD emitting the laser beam Lc, a laser beam source drive unit 14 that supplies power to the laser beam source LD, and a controller 54 that controls output of the laser beam source drive unit 14 based on detected results of the light intensity detection unit 35.

In addition, in the unit U1 of the portion on which the laser beam source LD is mounted, as shown in FIGS. 2A to 5B, a substrate 16 having improved thermal conductivity on which the laser beam source LD is placed, a temperature measurement member 17 that measures a temperature of the substrate 16, a temperature adjustment member 18 that contacts the substrate 16 and adjusts the temperature of the substrate 16, a heat dissipation member M15 that is disposed to contact the temperature adjustment member 18, and a circuit substrate 19 that is electrically connected to the temperature measurement member 17 and the laser beam source LD are provided.

As shown in FIG. 1, in the first embodiment of the present invention, in the laser beam source LD of the laser beam source module MD4, two colors of laser beam sources LD (RLD and GLD) such as red and green are provided. In addition, although it is not shown in detail, in order to emit the red and the green, two kinds of semiconductor laser elements are used. Accordingly, since the semiconductor laser elements are used, the laser beam Lc having high coherence (coherent) can be emitted from the laser beam source LD. Moreover, since the plurality of laser beam sources LD (two kinds and two sources in the first embodiment of the present invention) are provided in this way, the colors of the video VM visually confirmed by the observer ST can be plural, and thus, the video VM can be richly expressed.

Moreover, for example, as the semiconductor laser element, an element emitting light having wavelength of 642 nm or the like is appropriately used in the case of red, and an element emitting light having wavelength of 515 nm or the like is appropriately used in the case of green.

The laser beam source drive unit 14 of the laser beam source module MD4 is a drive circuit to which an operational amplifier is incorporated, and as shown in FIG. 1, a laser beam source drive unit 14R and a laser beam source drive unit 14G are connected to the laser beam sources LD (RLD and GLD), respectively, power is supplied to respective laser beam sources LD (RLD and GLD), and thus, respective laser beam sources LD (RLD and GLD) are driven.

The controller 54 of the laser beam source module MD4 controls the output of the laser beam source drive unit 14 (14R and 14G) based on the detected results of the light intensity detection unit 35 (35R and 35G), and as shown in FIG. 1, the controller is connected to each light intensity detection unit 35 (35R and 35G) and each laser beam source drive unit 14 (14R and 14G). Accordingly, even when the area has different colors and different display images, the output of each laser beam source LD (RLD and GLD) is adjusted by the controller 54, and light intensity (brightness) of each displayed video VM can be maintained at a desired value. Accordingly, the video VM visually confirmed by the observer ST can be richly expressed. Moreover, the controller 54 includes a function which adjusts the output change of the laser beam source LD according to the change of the temperature by the heat generation of the laser beam source LD in addition to a function which adjusts the output of the laser beam source LD based on the detected results of the light intensity detection unit 35.

Next, the unit U1 of the portion on which the laser beam source LD is mounted will be described with reference to FIGS. 2A to 5B. Moreover, the laser beam source LD shown in FIGS. 2A to 5B is either the red laser beam source LD or the green laser beam source LD, and thus, the unit U1 having the same configuration is provided with respect to the laser beam source LD having each color.

As shown in FIGS. 2A to 4B, the laser beam source LD uses a can type laser beam source in which the semiconductor laser element is mounted in a metal package, and is placed on a placement surface 16p of the substrate 16 having improved thermal conductivity. Moreover, the laser beam source LD is electrically connected to a wiring pattern 19p of the circuit substrate 19 disposed on a rear surface 16u (a surface opposite to the placement surface 16p) of the substrate 16. Moreover, although it is not shown, three pin terminals of the laser beam source LD are connected to wiring patterns 19p using solder.

In addition, in the first embodiment of the present invention, a metal substrate in which the substrate 16 and the circuit substrate 19 are integrally formed is used. In general, here, the metal substrate indicates a print wiring substrate having reinforced heat dissipation characteristics or heat resistance, and there are two types such as a metal base substrate in which a circuit is formed on a metal plate and a metal core substrate in which a metal plate is interposed to an inner portion of the substrate. In addition, as a metal material of the metal plate, a material having improved thermal conductivity such as aluminum (Al) or copper (Cu) is selected. In the first embodiment of the present invention, as shown in FIGS. 4B and 5B, the metal core substrate in which the metal core (metal plate) 16c is interposed to an inner portion of the substrate 16 is used, a print wiring formed on the rear surface 16u of the substrate 16 is used as the circuit substrate 19. Accordingly, the circuit substrate 19 having the wiring pattern 19p for supplying power, transmitting signal, or the like, and the substrate 16 for thermal conduction can be easily formed, and the circuit substrate 19 and the substrate 16 can be easily connected to each other. In addition, since the metal core substrate is used in the first embodiment of the present invention, the wiring can be also formed on the placement surface 16p side of the substrate 16, and thus, even when the laser beam source is not a dip type laser beam source LD used in the first embodiment of the present invention and is a surface mounting type laser beam source LD, the surface mounting type laser beam source can be mounted on the placement surface 16p side of the substrate 16 as it is.

In addition, as shown in FIGS. 2A, 3A, and 4A, the metal package of the laser beam source LD and a metal layer 16m provided on the placement surface 16p of the substrate 16 are connected by spot welding (Wd shown in the drawings), and thus, the laser beam source LD is fixed to the substrate 16. Moreover, as shown in FIGS. 4B and 5B, since the metal layer 16m and the metal core 16c are integrated with each other, the heat of the laser beam source LD is easily conducted to the metal core 16c. Moreover, a resist layer 16r is provided on the surface of the placement surface 16p other than a portion on which the laser beam source LD is placed, and thus, the surface of the placement surface other than this portion is protected from an external environment.

In addition, as shown in FIG. 3A, a connector CN1 for electric connection with respect to the outer portion of the unit U1 is mounted on the circuit substrate 19. In addition, although it is not shown, the laser beam source LD and the laser beam source drive unit 14 are connected to each other via a wiring pattern 19p and the connector CN1. Moreover, the wiring pattern 19p and the terminal of the connector CN1 are connected to each other by solder.

In addition, as shown in FIGS. 2B, 3B, and 5B, the temperature measurement member 17 for measuring the temperature of the substrate 16 is mounted on the circuit substrate 19, and one terminal portion 17s of the terminal of the temperature measurement member 17 is electrically connected to a wiring pattern 19p₁ of the circuit substrate 19. Moreover, at least a portion of the temperature measurement member 17 other than the one terminal portion 17s contacts the metal core 16c of the substrate 16 via a wiring pattern 19p₂, and as shown in FIG. 5B, the other terminal portion 17t of the terminal of the temperature measurement member 17 is electrically connected to the metal core 16c of the substrate 16 via the wiring pattern 19p₂. Accordingly, in the contact portion between the metal core 16c of the substrate 16, to which the heat of the laser beam source LD is easily conducted, and the temperature measurement member 17, the temperature is securely detected, and thus, the temperature of the laser beam source LD can be correctly measured.

In addition, the circuit substrate 19 is disposed on the rear surface 16u opposite to the placement surface 16p on which the laser beam source LD is placed, the temperature measurement member 17 is mounted on the circuit substrate 19, and thus, the laser beam source LD and the temperature measurement member 17, and the circuit substrate 19 are electrically connected to each other only on the rear surface 16u of the substrate 16. As described above, the connection is easily performed, and thus, a problem of the related art, in which it is difficult to electrically connect the temperature sensor 913 and the circuit substrate 801, can be solved.

Moreover, the wiring pattern 19p₂ connected to the substrate 16 is connected to a grand terminal G1 (refer to FIG. 3A) of the connector CN1, and although it is not shown, the substrate 16 and the other terminal portion 17t of the temperature measurement member 17 are grounded to the outside via the wiring pattern 19p₂ of the circuit substrate 19 and the grand terminal G1 of the connector CN1. Accordingly, the wiring to the other terminal portion 17t can be omitted. Therefore, the temperature measurement member 17 can be easily mounted, and the laser beam source module MD4 can be easily manufactured. In addition, the resist layer 19r is provided on the surface of the circuit substrate 19, and thus, is protected from the external environment.

In addition, in the first embodiment of the present invention, as the temperature measurement member 17, a chip type thermistor is used. Therefore, a surface mounting of the temperature measurement member can be performed on the circuit substrate 19. According to the effect, unlike the related art, difficulty of the connection between the temperature sensor 913 disposed to contact a side surface of the laser holder 916 and the circuit substrate 801 can be resolved. Accordingly, the laser beam source module MD4 can be easily manufactured.

As shown in FIGS. 2A to 5B, the temperature adjustment member 18 which adjusts the temperature of the substrate 16 is provided on the rear surface 16u of the substrate 16. As the temperature adjustment member 18, a Peltier element which is a semiconductor element using Peltier effects is appropriately used. Moreover, although it is not shown in detail, one surface side (Z1 side in FIGS. 4A and 4B) of the temperature adjustment member 18 is connected to the metal core 16c of the substrate 16 via the metal layer 16n. In addition, the cooling effect on the metal core 16c is adjusted by the temperature adjustment member 18, and thus, the temperature of the substrate 16 can be adjusted. Accordingly, the temperature of the laser beam source LD can be adjusted via the substrate 16 (metal core 16c) having improved thermal conductivity based on the temperature detected by the temperature measurement member 17. Therefore, instability of the radiation of the laser beam Lc due to the change of the temperature can be suppressed, and thus, the display image visually confirmed by the observer ST can be stably displayed.

In addition, as shown in FIGS. 2A to 5B, the heat dissipation member M15 is disposed on the rear surface 16u of the substrate 16 to contact the other surface side (Z2 side in FIGS. 4A and 4B) of the temperature adjustment member 18. As the heat dissipation member M15, a heat dissipation plate (so-called heat sink) using a material having improved thermal conductivity such as aluminum (Al) or copper (Cu) is appropriately used. Accordingly, the heat dissipation from the temperature adjustment member 18 can be more effectively performed. Therefore, the temperature of the laser beam source LD can be securely adjusted with improved responsiveness via the substrate 16 having improved thermal conductivity.

Finally, the image generation unit 11, the optical member OP, and the light intensity detection unit 35 of the video display device 101 will be described.

As shown in FIG. 1, the image generation unit 11 of the video display device 101 is configured to include a holographic optical element 31 which diffracts the laser beam Lc to make video light Lf, a driver 51 which drives the holographic optical element 31, and a central processing unit 71 which prepares a “hologram pattern”.

The holographic optical element 31 of the image generation unit 11 has a function which diffracts the laser beam Lc from the laser beam source LD to make the video light Lf. Specifically, in the first embodiment of the present invention, a phase modulation type liquid crystal on silicon (LCOS) is used, coherent light (laser beam Lc) is radiated to the “hologram pattern” written to the phase modulation type LCOS, and thus, diffracted light is generated and is emitted as the video light Lf through a Fourier lens FL1 shown in FIG. 1. In addition, the intensity and the phase of the light are recorded on the “hologram pattern”.

In addition, as shown in FIG. 1, the driver 51 is connected to the holographic optical element 31, and the driver 51 has a function which writes the “hologram pattern” prepared by the central processing unit 71 to the phase modulation type LCOS as necessary. Moreover, in the first embodiment of the present invention, a desired display image is generated using the holographic optical element 31, the output of the laser beam source LD can be matched for each display image of the displayed video VM, and thus, the output adjustment of the laser beam source drive unit 14 can be finely performed.

The optical member OP of the video display device 101 is mainly configured of optical components which introduce the video light Lf from the holographic optical element 31 to the windshield WS of the vehicle, and in the first embodiment of the present invention, as shown in FIG. 1, the optical member includes planar mirrors (12 and 22) which change the optical path of the laser beam Lc, an optical lens 32 which collects or collimates the light, a slitter 52 which defines the display range of a display screen, a diffuser 13 which diffuses the video light Lf, and an optical filter F5 which is disposed on the optical path of the video light Lf. Moreover, the optical member also includes an optical lens 42 which collects or collimates the laser beam Lc from the laser beam source LD.

The planar mirrors (12 and 22), the optical lens 32, and the optical lens 42 of the optical member OP use the optical components which are generally used, and do not have particular specifications. Moreover, instead of the planar mirrors (12 and 22), a curved mirror may be used. Moreover, the present invention is not limited to the combination of the planar mirrors (12 and 22) or the optical lenses (32 and 42) shown in FIG. 1.

The slitter 52 of the optical member OP passes through most of the radiation range of the video light Lf, and the range corresponding to the video light Lf passing through the slitter becomes the display image of the video VM (refer to FIG. 1) which is visually confirmed by the observer ST, that is, the display image.

As shown in FIG. 1, the diffuser 13 of the optical member OP is disposed at the rear side (an emitting direction of the video light Lf) of the slitter 52 in the optical path of the video light Lf, and diffuses the transmitted video light Lf. Moreover, a drive unit 13d which drives the diffuser 13 is connected to the diffuser 13 and rotates the diffuser 13. Accordingly, directivity of the video light Lf which is a coherent laser beam Lc is decreased. Therefore, a speckle pattern due to the coherent light can be decreased, and thus, quality of the video VM which is visually confirmed by the observer ST can be improved. Here, the speckle pattern means a fine interference fringe which is generated by interference of scattered lights scattered at each portion on an irradiated object when light having high coherence (coherent) abuts the irradiated object and is scattered. Moreover, in the first embodiment of the present invention, the diffuser 13 is rotated. However, the present invention is not limited to this, and for example, the diffuser may be vibrated.

The light intensity detection unit 35 of the video display device 101 detects the light intensity of the video light Lf, and as shown in FIG. 1, is disposed in the vicinity of the slitter 52, and two of the light intensity detection units 35R and the light intensity detection unit 35G are provided to correspond two of the laser beam source RLD and the laser beam source GLD. Moreover, with respect to the video light Lf radiated to the light intensity detection unit 35R and the light intensity detection unit 35G, the intensity for each color of the red and the green is separately detected. As the light intensity detection unit 35, a photodiode (PD) is appropriately used.

In the video display device 101 of the first embodiment of the present invention having the above-described configuration, the effects will be described below.

In the video display device 101 of the first embodiment of the present invention, the laser beam source LD is placed on the substrate 16 having improved thermal conductivity, the temperature measurement member 17 detecting the temperature of the substrate 16 and the temperature adjustment member 18 adjusting the temperature of the substrate 16 are provided, and a portion of the temperature measurement member 17 is connected to the substrate 16. Accordingly, the temperature of the laser beam source LD can be detected via the substrate 16 having improved thermal conductivity, and the temperature of the substrate 16 can be adjusted by the temperature adjustment member 18 based on the detected temperature. Therefore, the temperature of the laser beam source LD can be adjusted via the substrate 16 having improved thermal conductivity. Accordingly, instability of the radiation of the laser beam Lc due to the change of the temperature can be suppressed, and the display image visually confirmed by the observer ST can be stably displayed.

Moreover, since at least a portion of the temperature measurement member 17 other than the one terminal portion 17s contacts the substrate 16, the detection of the temperature of the substrate 16 can be securely performed at the contact portion, and thus, the temperature of the laser beam source LD mounted on the substrate 16 can be correctly measured. Accordingly, the instability of the radiation of the laser beam Lc due to the change of the temperature can be further suppressed. Moreover, the other terminal portion 17t of the terminal of the temperature measurement member 17 is electrically connected to the substrate 16 to be grounded, and thus, the wiring to the other terminal portion 17t can be omitted. Accordingly, the temperature measurement member 17 can be easily mounted, and thus, the laser beam source module MD4 and the video display device 101 can be easily manufactured.

Moreover, the substrate 16 and the circuit substrate 19 are integrally formed using the metal substrate, and thus, the circuit substrate 19 having the wiring pattern 19p for supplying power, transmitting signal, or the like, and the substrate 16 for performing thermal conduction can be easily formed, and the circuit substrate 19 and the substrate 16 can be easily connected to each other. In addition, in the first embodiment of the present invention, since the metal core substrate is used, the wiring can be also formed on the placement surface 16p side of the substrate 16, and thus, even when the laser beam source is not a dip type laser beam source LD used in the first embodiment of the present invention and is a surface mounting type laser beam source LD, the surface mounting type laser beam source can be mounted on the placement surface 16p side of the substrate 16 as it is.

In addition, the temperature measurement member 17 is a chip type thermistor, and thus, the surface mounting of the temperature measurement member can be performed on the circuit substrate 19. Accordingly, compared to the configuration of the related art, the laser beam source module MD4 and the video display device 101 can be more easily manufactured.

Moreover, the laser beam source module MD4 includes the heat dissipation member M15 disposed to contact the temperature adjustment member 18, and thus, heat dissipation from the temperature adjustment member 18 can be effectively performed. Accordingly, the temperature of the laser beam source LD can be securely adjusted with improved responsiveness via the substrate 16 having improved thermal conductivity.

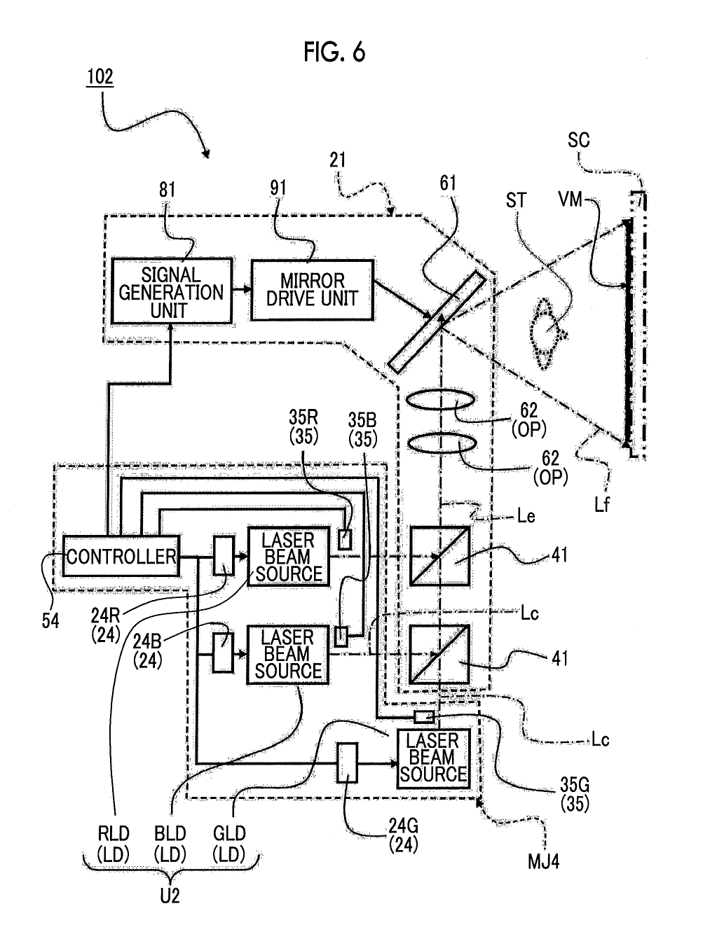

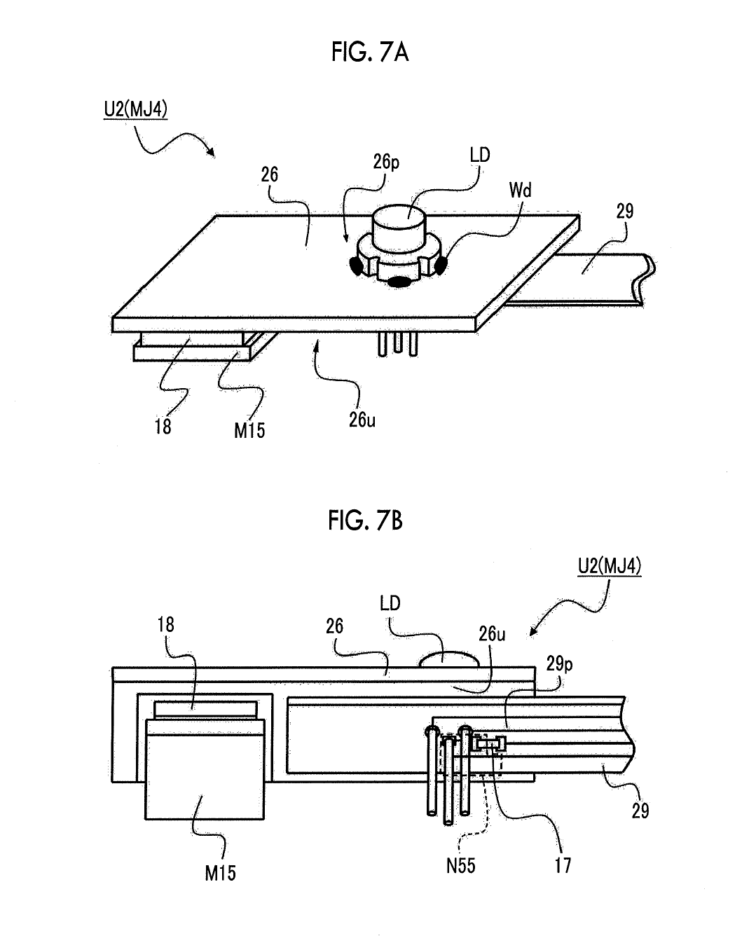

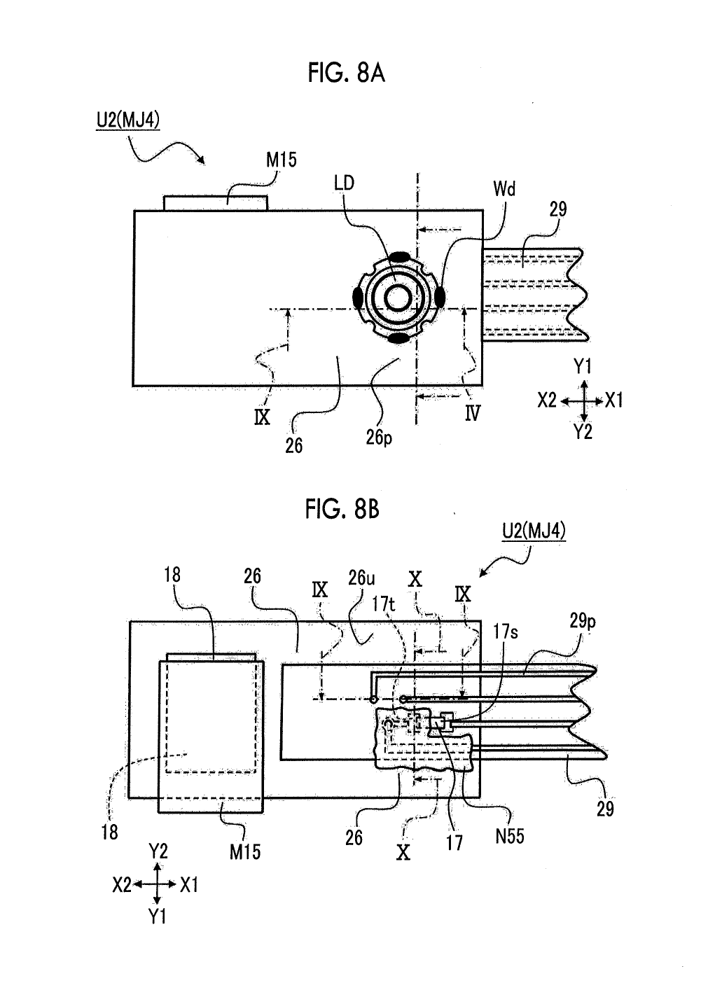

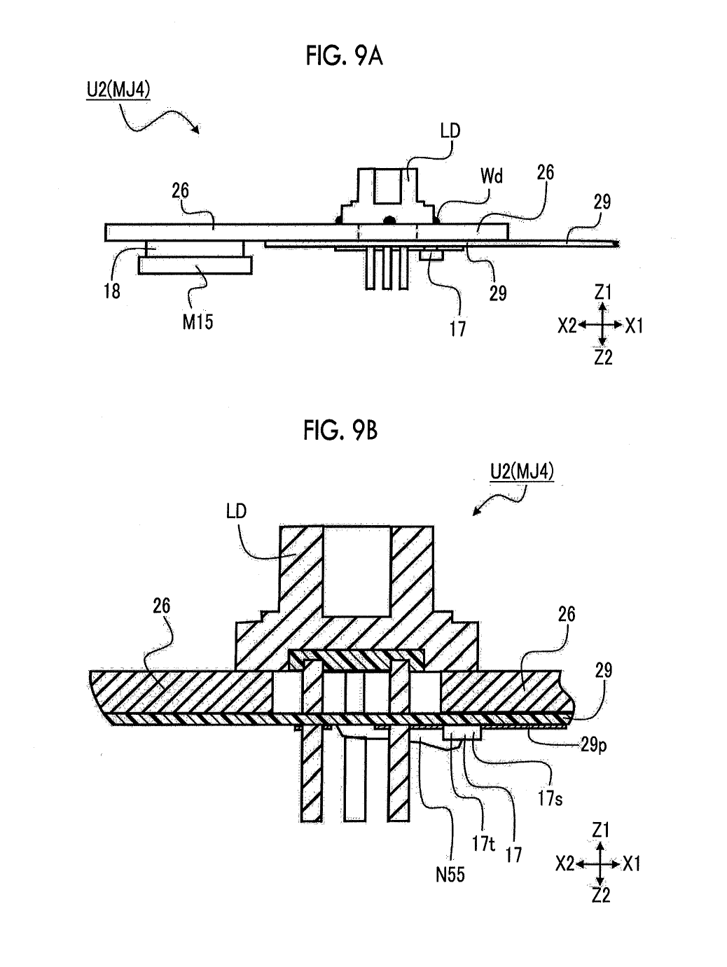

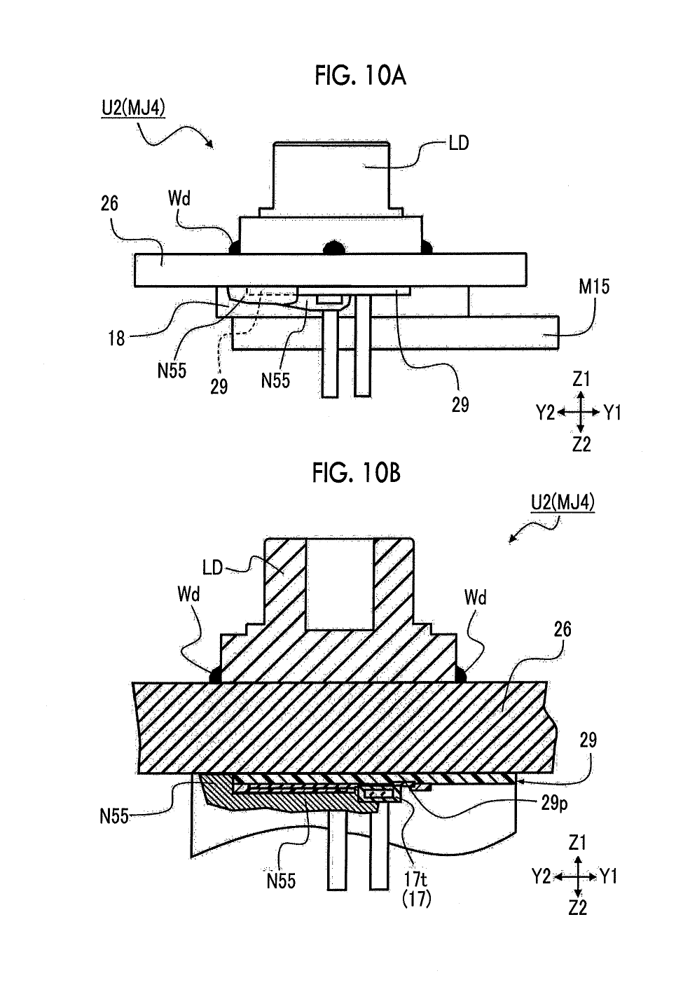

FIG. 6 is a configuration view illustrating a video display device 102 of a second embodiment of the present invention. FIGS. 7A and 7B are configuration views illustrating a laser beam source module according to the video display device of the second embodiment of the present invention, FIG. 7A is a top perspective view of a unit U2 on which the laser beam source LD is mounted, and FIG. 7B is a bottom perspective view of the unit U2 on which the laser beam source LD is mounted. Moreover, for ease of description, a thermal conduction member N55 is shown by a dashed line. FIGS. 8A and 8B are configuration views illustrating the laser beam source module according to the video display device of the second embodiment of the present invention, FIG. 8A is a top view of the unit U2 on which the laser beam source LD is mounted, and FIG. 8B is a bottom view of the unit U2 on which the laser beam source LD is mounted. FIGS. 9A and 9B are configuration views illustrating the laser beam source module according to the video display device of the second embodiment of the present invention, FIG. 9A is a front view when the module is viewed from an Y2 side shown in FIG. 7A, and FIG. 9B is a cross-sectional view taken along line IX-IX shown in FIGS. 8A and 8B. FIGS. 10A and 10B are configuration views illustrating the laser beam source module according to the video display device of the second embodiment of the present invention, FIG. 10A is a side view when the module is viewed from an X1 side shown in FIG. 7A, and FIG. 10B is a cross-sectional view taken along line X-X shown in FIGS. 8A and 8B. Moreover, the video display device 102 of the second embodiment is different from that of the first embodiment in that an image generation unit 21 and the unit U2 on which the laser beam source LD is mounted are different from each other. In addition, the same reference numerals are assigned to the same configurations as the first embodiment, and the description thereof is omitted.

As shown in FIG. 6, the video display device 102 of the second embodiment of the present invention is mounted on a laser projector for office work, or the like, and is used as a video display device which provides a video with respect to a viewer (observer) ST.

As shown in FIG. 6, the video display device 102 of the second embodiment of the present invention is configured to include a laser beam source module MJ4 which includes a laser beam source LD emitting the laser beam Lc, and the image generation unit 21 which generates a desired display image from the laser beam Lc. Moreover, the video display device 102 includes an optical member OP which introduces the video light Lf of the display image to a screen SC, and the light intensity detection unit 35 which detects light intensity of the laser beam Lc. In addition, the video VM of the display image generated by the image generation unit 21 is projected to the screen SC, and is observed (is visually confirmed) by the observer (viewer) ST.

First, the laser beam source module MJ4 of the video display device 102 will be described. As shown in FIG. 6, the laser beam source module MJ4 is configured to include the unit U2 that includes the laser beam source LD emitting the laser beam Lc, a laser beam source drive unit 24 that supplies power to the laser beam source LD, and the controller 54 that controls output of the laser beam source drive unit 24 based on detected results of the light intensity detection unit 35.

In addition, in the unit U2 of the portion on which the laser beam source LD is mounted, as shown in FIGS. 2A to 5B, a substrate 26 having improved thermal conductivity on which the laser beam source LD is placed, the temperature measurement member 17 that measures the temperature of the substrate 26, the thermal conduction member N55 having improved thermal conductivity, the temperature adjustment member 18 that contacts the substrate 26 and adjusts the temperature of the substrate 26, the heat dissipation member M15 that is disposed to contact the temperature adjustment member 18, and a circuit substrate 29 that is electrically connected to the temperature measurement member 17 and the laser beam source LD are provided.

As shown in FIG. 6, in the second embodiment of the present invention, in the laser beam source LD of the laser beam source module MJ4, three colors of laser beam sources LD (RLD, GLD, and BLD) such as red, green, and blue are provided. Moreover, although it is not shown in detail, in order to emit the red, the green, and blue, three kinds of semiconductor laser elements are used. Accordingly, since the semiconductor laser elements are used, the laser beam Lc having high coherence (coherent) can be emitted from the laser beam source LD. Moreover, since the plurality of laser beam sources LD (three kinds and three sources in the second embodiment of the present invention) are provided in this way, the colors of the video VM visually confirmed by the observer ST can be in plural, and thus, the video VM can be richly expressed.

Moreover, for example, as the semiconductor laser element, an element emitting light having wavelength of 642 nm or the like is appropriately used in the case of red, an element emitting light having wavelength of 515 nm or the like is appropriately used in the case of green, and an element emitting light having wavelength of 445 nm or the like is appropriately used in the case of blue.

The laser beam source drive unit 24 of the laser beam source module MJ4 is a drive circuit to which an operational amplifier is incorporated, and as shown in FIG. 6, a laser beam source drive unit 24R, a laser beam source drive unit 24G, and a laser beam source drive unit 24B are connected to the laser beam sources LD (RLD, GLD, and BLD), respectively, power is supplied to respective laser beam sources LD (RLD, GLD, and BLD), and thus, respective laser beam sources LD (RLD, GLD, and BLD) are driven.

Similar to the first embodiment, the controller 54 of the laser beam source module MJ4 controls the output of the laser beam source drive unit 24 (24R, 24G, and 24B) based on the detected results of the light intensity detection unit 35 (35R, 35G, and 35B), and as shown in FIG. 6, the controller is connected to each light intensity detection unit 35 (35R, 35G, and 35B) and each laser beam source drive unit 24 (24R, 24G, and 24B). Accordingly, even when the area has different colors and different display images, the output of each laser beam source LD (RLD, GLD, and BLD) is adjusted by the controller 54, and light intensity (brightness) of each displayed video VM can be maintained at a desired value. Therefore, the video VM visually confirmed by the observer ST can be richly expressed. Moreover, the controller 54 includes a function which adjusts the output change of the laser beam source LD according to the change of the temperature by the heat generation of the laser beam source LD in addition to a function which adjusts the output of the laser beam source LD based on the detected results of the light intensity detection unit 35.

Next, the unit U2 of the portion on which the laser beam source LD is mounted will be described with reference to FIGS. 7A to 10B. Moreover, the laser beam source LD shown in FIGS. 7A to 10B is any one of the red laser beam source LD, the green laser beam source LD, and the blue laser beam source LD, and thus, the unit U2 having the same configuration is provided with respect to the laser beam source LD having each color.

Similar to the first embodiment, as shown in FIGS. 7A to 9B, the laser beam source LD uses a can type laser beam source in which the semiconductor laser element is mounted in the metal package, and is placed on a placement surface 26p of the substrate 26 having improved thermal conductivity. Moreover, the laser beam source LD is electrically connected to a wiring pattern 29p of the circuit substrate 29 disposed on a rear surface 26u (a surface opposite to the placement surface 26p) of the substrate 26. In addition, three pin terminals of the laser beam source LD are connected to wiring patterns 29p using solder.

As shown in FIGS. 7A, 8A, and 9B, the substrate 26 is formed in a rectangular plate shape using a material having improved thermal conductivity such as aluminum (Al) or copper (Cu). In addition, the laser beam source LD is placed on the substrate 26, the placement surface 26p of the substrate 26 and the metal package of the laser beam source LD are connected to each other by spot welding (Wd shown in the drawings), and the laser beam source LD is fixed to the substrate 26. Accordingly, the heat generated due to the laser beam source LD can be easily conducted to the substrate 26.

The circuit substrate 29 is a flexible printed circuit (FPC) which is widely used in general, and as shown in FIGS. 7B and 8B, the circuit substrate 29 is disposed on the rear surface 26u (the surface opposite to the placement surface 26p) of the substrate 26 and is electrically connected to the wiring pattern 29p of the circuit substrate 29 and three pin terminals of the laser beam source LD. Moreover, although it is not shown, the circuit substrate 29 is extended for electric connection between the unit U2 and the outside, and for example, the laser beam source LD and the laser beam source drive unit 24 are connected to each other via the wiring pattern 29p.

Moreover, the circuit substrate 29 is the flexible printed circuit, and thus, the flexible printed circuit can be disposed on the rear surface 26u side of the substrate 26 with a certain degree of freedom. For example, in a case where the mounting angle of the laser beam source LD is changed due to optical-axis alignment or the like of the laser beam source LD, even when some misalignment occurs in the disposition of three pin terminals of the laser beam source LD on the rear surface 26u side of the substrate 26, the flexible printed circuit can be disposed to match the misalignment. Accordingly, the laser beam source module MJ4 can be more easily manufactured.

In addition, as shown in FIGS. 7B, 8B, and 10B, the temperature measurement member 17 for measuring the temperature of the substrate 26 is mounted on the circuit substrate 29 and is electrically connected to the wiring pattern 29p of the circuit substrate 29. Accordingly, the laser beam source LD and the temperature measurement member 17, and the circuit substrate 29 are electrically connected to each other only on the rear surface 26u of the substrate 26. As described above, the connection is easily performed, and thus, a problem of the related art, in which it is difficult to electrically connect the temperature sensor 913 and the circuit substrate 801, can be solved.

In addition, also in the second embodiment of the present invention, as the temperature measurement member 17, a chip type thermistor is used. Therefore, a surface mounting of the temperature measurement member can be performed on the circuit substrate 29. According to the effect, unlike the related art, difficulty of the connection between the temperature sensor 913 disposed to contact a side surface of the laser holder 916 and the circuit substrate 801 can be solved. Accordingly, the laser beam source module MJ4 can be easily manufactured.

Moreover, as shown in FIG. 8B, the thermal conduction member N55 having improved thermal conductivity is disposed on the rear surface 26u side of the substrate 26, the thermal conduction member N55 covers a portion of the temperature measurement member 17 other than the other terminal portion 17t and the one terminal portion 17s of the terminal of the temperature measurement member 17, and covers a portion of the circuit substrate 29 and a portion of the substrate 26 over the circuit substrate 29 and the substrate 26. Accordingly, a portion of the temperature measurement member 17 and the substrate 26 are connected to each other via the thermal conduction member N55. Therefore, the detection of the temperature of the substrate 26 can be securely performed by the temperature measurement member 17 via the thermal conduction member N55.

Moreover, in the second embodiment of the present invention, the thermal conduction member N55 uses a solder member. Accordingly, when the electric connection between the temperature measurement member 17 and the wiring pattern 29p of the circuit substrate 29 is performed, the temperature measurement member 17 and the substrate 26 can be simultaneously connected to each other. Therefore, the laser beam source module MJ4 can be easily manufactured. In addition, the solder member is appropriately used as the thermal conduction member N55. However, a thermal conductive adhesive material may be used as the thermal conduction member N55.

In addition, as shown in FIGS. 7A to 10B, the temperature adjustment member 18 which adjusts the temperature of the substrate 26 is provided on the rear surface 26u of the substrate 26. Similar to the first embodiment, as the temperature adjustment member 18, a Peltier element which is a semiconductor element using Peltier effects is appropriately used. In addition, a cooling effect on the substrate 26 is adjusted by the temperature adjustment member 18, and thus, the temperature of the substrate 26 can be adjusted. Accordingly, the temperature of the laser beam source LD can be adjusted via the substrate 26 having improved thermal conductivity based on the temperature detected by the temperature measurement member 17. Therefore, instability of the radiation of the laser beam Lc due to the change of the temperature can be suppressed, and thus, the display image visually confirmed by the observer ST can be stably displayed.

Moreover, similar to the first embodiment of the present invention, as shown in FIGS. 7A to 10B, the heat dissipation member M15 is disposed on the rear surface 26u of the substrate 26 to contact the other surface side (Z2 side in FIGS. 9A and 9B) of the temperature adjustment member 18. As the heat dissipation member M15, a heat dissipation plate (so-called heat sink) using a material having improved thermal conductivity such as aluminum (Al) or copper (Cu) is appropriately used. Accordingly, the heat dissipation from the temperature adjustment member 18 can be more effectively performed. Therefore, the temperature of the laser beam source LD can be securely adjusted with improved responsiveness via the substrate 26 having improved thermal conductivity.

Finally, the image generation unit 21, the optical member OP, and the light intensity detection unit 35 of the video display device 102 will be described.

As shown in FIG. 6, the image generation unit 21 of the video display device 102 is configured to include a mirror unit 41 which combines three laser beams Lc and emits the beams, a drive scanning mirror 61 that scans the laser beam Le emitted from the mirror unit 41 to make the video light Lf, a signal generation unit 81 that generates a drive signal having a predetermined frequency, and a mirror drive unit 91 that drives the drive scanning mirror 61 based on the drive signal generated by the signal generation unit 81.

For example, the mirror unit 41 of the image generation unit 21 is a diachronic mirror or the like which transmits the light having a specific wavelength and reflects the light having wavelengths other than the above-mentioned wavelength, combines the laser beam Lc of each color from the plurality of laser beams Lc to make the laser beam Le having one optical axis, and emits the laser beam Le to the drive scanning mirror 61.

The drive scanning mirror 61 of the image generation unit 21 has a function as scanning means for reflecting the laser beam Le, which is emitted from the laser beam source LD and is combined by the mirror unit 41, in a two-dimensional direction, by electromagnetic drive, and for projecting and scanning the video light Lf to the screen SC. The drive scanning mirror 61 appropriately uses a MEMS mirror which uses a Micro Electro Mechanical System (MEMS) technology. The MEMS mirror is a minute device which is manufactured by collecting mechanical mechanisms and electric circuits on a silicon wafer using a micromachining technology, and a reduction in the overall size of the apparatus can be improved using the MEMS mirror.

The signal generation unit 81 of the image generation unit 21 generates a drive signal for driving the drive scanning mirror 61 in a main scanning direction and a sub scanning direction orthogonal to the main scanning direction according to the control of the controller 54. Particularly, the signal generation unit 81 functions as scan signal generating means, generates a pulse signal that is a drive signal by which the drive scanning mirror 61 performs a main scanning on the laser beam Le in a right-left direction, and generates a drive signal by which the drive scanning mirror 61 performs a sub scanning on the laser beam Le in an up-down direction.

The mirror drive unit 91 of the image generation unit 21 is connected to the drive scanning mirror 61, and drives the drive scanning mirror 61 based on the drive signal generated in the signal generation unit 81. Particularly, the mirror drive unit 91 functions as driving means for reciprocating the drive scanning mirror 61 in the main scanning direction (right-left direction) according to the pulse signal generated in the signal generation unit 81.

The optical member OP of the video display device 102 is mainly configured of an optical component which introduces the laser beam Le emitted from the mirror unit 41 to the drive scanning mirror 61, and in the second embodiment of the present invention, as shown in FIG. 6, includes an optical lens 62 which collects or collimates the light. Moreover, the optical lens 62 of the optical member OP is an optical component, which is generally used, and does not have a particular specification.

The light intensity detection unit 35 of the video display device 102 detects the light intensity of the video light Lf, and as shown in FIG. 6, is disposed in the vicinity of the laser beam source LD, and three of the light intensity detection unit 35R, the light intensity detection unit 35G, and the light intensity detection unit 35B are provided according to three of the laser beam source RLD, the laser beam source GLD, and the laser beam source BLD. Moreover, the light intensity detection unit separately detects the intensity for each color of the red, the green, and the blue with respect to the laser beam Lc radiated to the light intensity detection unit 35R, the light intensity detection unit 35G, and the light intensity detection unit 35B. The light intensity detection unit 35 appropriately uses a photodiode (PD).

In the video display device 102 of the second embodiment of the present invention having the above-described configuration, the effects will be described below.

In the video display device 102 of the second embodiment of the present invention, the laser beam source LD is placed on the substrate 26 having improved thermal conductivity, the temperature measurement member 17 detecting the temperature of the substrate 26 and the temperature adjustment member 18 adjusting the temperature of the substrate 26 are provided, and a portion of the temperature measurement member 17 is connected to the substrate 26. Accordingly, the temperature of the laser beam source LD can be detected via the substrate 26 having improved thermal conductivity, and the temperature of the substrate 26 can be adjusted by the temperature adjustment member 18 based on the detected temperature. Therefore, the temperature of the laser beam source LD can be adjusted via the substrate 26 having improved thermal conductivity. Accordingly, instability of the radiation of the laser beam Lc due to the change of the temperature can be suppressed, and the display image visually confirmed by the observer ST can be stably displayed.

Moreover, since a portion of the temperature measurement member 17 and the substrate 26 are connected to each other via the thermal conduction member N55, the detection of the temperature of the substrate 26 can be securely performed by the temperature measurement member 17 via the thermal conduction member N55. Accordingly, the instability of the radiation of the laser beam Lc due to the change of the temperature can be further suppressed.

In addition, since the thermal conduction member N55 is a solder member, when the electric connection between the temperature measurement member 17 and the wiring pattern 29p of the circuit substrate 29 is performed, the temperature measurement member 17 and the substrate 26 can be simultaneously connected to each other. Therefore, the laser beam source module MJ4 can be easily manufactured.

Moreover, the circuit substrate 29 is the flexible printed circuit, and thus, the flexible printed circuit can be disposed on the rear surface 26u side of the substrate 26 with a certain degree of freedom. For example, in the case where the mounting angle of the laser beam source LD is changed due to the optical-axis alignment or the like of the laser beam source LD, even when some misalignment occurs in the disposition of three pin terminals of the laser beam source LD on the rear surface 26u side of the substrate 26, the flexible printed circuit can be disposed to match the misalignment. Accordingly, the laser beam source module MJ4 can be more easily manufactured.

In addition, the temperature measurement member 17 is a chip type thermistor, and thus, the surface mounting of the temperature measurement member can be performed on the circuit substrate 29. Accordingly, compared to the configuration of the related art, the laser beam source module MJ4 and the video display device 102 can be more easily manufactured.

Moreover, the laser beam source module MJ4 includes the heat dissipation member M15 disposed to contact the temperature adjustment member 18, and thus, heat dissipation from the temperature adjustment member 18 can be effectively performed. Accordingly, the temperature of the laser beam source LD can be securely adjusted with improved responsiveness via the substrate 26 having improved thermal conductivity.

In addition, the present invention is not limited to the above-described embodiments, and for example, the present invention may be modified as follows, and the modifications are also included in the technical scope of the present invention.

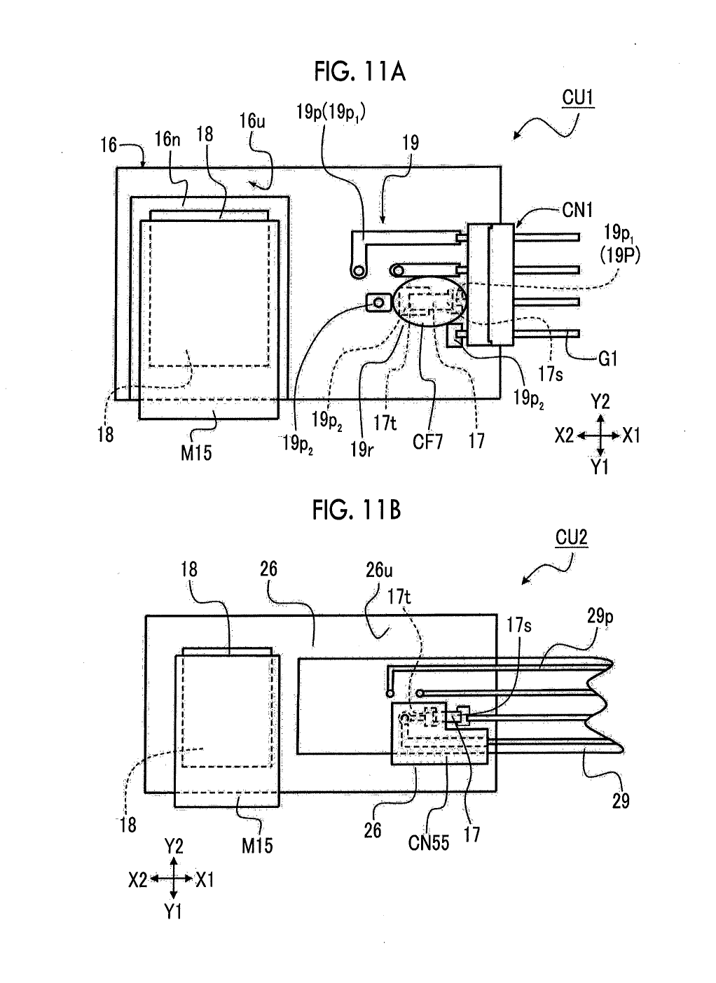

FIGS. 11A and 11B are views illustrating modifications of the embodiment of the present invention, FIG. 11A is a bottom view of a unit CU1 of a first modification of the first embodiment, and FIG. 11B is a bottom view of a unit CU2 of a third modification of the first embodiment.

First Modification

The unit CU1 including a sealing member CF7 shown in FIG. 11A may be configured with respect to the unit U1 of the first embodiment. According to the sealing member CF7, adverse effects to the temperature measurement member 17 due to condensation in the portion can be prevented.

Second Modification

In the first embodiment, the metal substrate is used as the substrate 16 and the circuit substrate 19 and the substrate 16 and the circuit substrate 19 are appropriately configured to be integrated with each other. However, a plate material such as aluminum or copper is used as the substrate, a printed wiring board is used as the circuit substrate, and the substrate and the circuit substrate may be separately configured.

Third Modification

In the second embodiment, the solder member is appropriately used as the thermal conduction member N55. However, the present invention is not limited to this, and for example, as shown in FIG. 11B, a sheet-like thermal conduction member CN55 may be used.

Third Modification

In the embodiments, the chip type thermistor is appropriately used as the temperature measurement member 17. However, the present invention is not limited to this, and for example, a lead type thermistor may be also used.

Fourth Modification

In the embodiments, two kinds of laser beam sources LD (RLD and GLD) or three kinds of laser beam sources LD (RLD, GLD, and BLD) are used. However, four kinds of beam sources, to which yellow is added, may be used, and four kinds or more of beam sources may be used. At this time, the laser beam source drive unit may be provided so as to correspond to the kind of the beam source. On the other hand, one kind of beam source may be used.

Fifth Modification

In the embodiments, the can type laser beam source in which the semiconductor laser element is mounted onto the metal package is used. However, the present invention is not limited to this, and for example, a package type using synthetic resin may be used.

Sixth Modification

The embodiments are applied to a head-up display (HUD) mounted on a vehicle or a laser projector. However, the present invention is not limited to this, and the present invention may be also applied to a three-dimensional display or a head mounted display (HMD).

The present invention is not limited to the above-described embodiments and modifications, and may be appropriately modified as long as the modifications do not depart from the scope of the invention.

It should be understood by those skilled in the art that various modifications, combinations, sub-combinations and alterations may occur depending on design requirements and other factors insofar as they are within the scope of the appended claims of the equivalents thereof.

What is claimed is:

1. A video display device allowing an observer to observe video of a display image, comprising:
a laser beam source module including a laser beam source emitting a laser beam and a laser beam source drive unit that supplies power to the laser beam source; and
an image generation unit that generates a desired display image from the laser beam,
wherein the laser beam source module includes:
a substrate on which the laser beam source is placed and which has improved thermal conductivity;
a temperature measurement member that measures a temperature of the substrate;
a temperature adjustment member that contacts the substrate and adjusting the temperature of the substrate; and
a circuit substrate that electrically connects the temperature measurement member and the laser beam source,
wherein the circuit substrate is disposed on a rear surface opposite to a placement surface on which the laser beam source is placed,
wherein the temperature measurement member is mounted on the circuit substrate, and
wherein a portion of the temperature measurement member is connected to the substrate.

2. The video display device according to claim 1,
wherein one terminal portion of a terminal of the temperature measurement member is electrically connected to the circuit substrate, and
wherein at least a portion of the temperature measurement member other than the one terminal portion contacts the substrate, and the other terminal portion of the terminal of the temperature measurement member is electrically connected to the substrate to be grounded.

3. The video display device according to claim 1,
wherein the substrate and the circuit substrate comprises a metal substrate integrally formed of the substrate and the circuit substrate.

4. The video display device according to claim 1,
wherein the laser beam source module includes a thermal conduction member having improved thermal conductivity, and
wherein a portion of the temperature measurement member and the substrate are connected to each other via the thermal conduction member.

5. The video display device according to claim 4,
wherein the thermal conduction member comprises a solder member.

6. The video display device according to claim 4,
wherein the circuit substrate comprises a flexible printed circuit.

7. The video display device according to claim 1,
wherein the temperature measurement member comprises a chip type thermistor.

8. The video display device according to claim 1,
wherein the laser beam source module includes a heat dissipation member disposed to contact the temperature adjustment member.
